(19) United States
(12) Patent Application Publication
(10) Pub. No.: US 2025/0364276 A1
(43) Pub. Date: Nov. 27, 2025

(54) TUNABLE LOW-COST PASSIVATION COATING FOR FACILITATING FLUXLESS BONDING OF COPPER SOLDER INTERCONNECTS IN FLIP CHIP ASSEMBLY

(71) Applicant: University of North Texas, Denton, TX (US)

(72) Inventors: Oliver Ming-Ren Chyan, Denton, TX (US); Ashish Salunke, Boise, ID (US); Kevin Antony Jesu Durai, Denton, TX (US); Dinesh Kumar Kumaravel, Denton, TX (US)

(21) Appl. No.: 18/674,810

(22) Filed: May 24, 2024

(51) Int. Cl. H01L 21/60; H01L 21/67; H01L 21/768; H01L 23/00

(52) U.S. Cl. CPC H01L 21/60; H01L 21/6704; H01L 21/67069; H01L 21/76828; H01L 24/05; H01L 24/08; H01L 24/13; H01L 24/16; H01L 2021/6006; H01L 2021/60097; H01L 2021/60247; H01L 2224/05147; H01L 2224/08113; H01L 2224/13147; H01L 2224/1357; H01L 2224/13693; H01L 2224/16238

(57) ABSTRACT

The invention provides improved techniques for bonding copper to solder or other types of flip chip devices using a passivation coating on copper. The surface of a substrate is cleaned prior to mounting a flip chip device onto the substrate. The substrate is rinsed to remove residual artifacts remaining on the surface subsequent to the cleaning. Subsequent to the rinsing, a protective coating is applied to the surface of the substrate to produce a coated substrate. Copper pillars with solder caps extending from the flip chip device are bonded to metallic features on the surface of the coated substrate.

### TECHNICAL FIELD

The present disclosure generally relates to the bonding of metallic devices and, more particularly, to techniques for reducing the oxidation of copper bonding substrates; this oxidation typically happens during the bonding of Cu pillars with solder caps on a Cu substrate, a process used in flip-chip or wafer-level bonding applications.

### BACKGROUND OF THE INVENTION

Copper (Cu) has rapidly replaced gold (Au) as the preferred bonding material in microelectronic packaging due to its higher electrical conductivity, lower cost, and better mechanical strength, which leads to reduced pad size and pad pitch. Advancements in flip-chip assembly and direct-wafer bonding technology have also reduced the form factor and packaging size of high-density input/output (I/O) devices. However, the bonding process for bonding solder-capped copper pillars of a flip chip to matching bond pads of external circuitry, such as a printed circuit board (PCB) composed of a flexible substrate, faces non-wettability challenges due to the formation of copper oxides. Copper rapidly oxidizes when heat is applied to an environment containing oxygen. Also, the temperatures required for soldering and reflow (typically 220-260° C.) can swiftly oxidize copper. Consequently, it is imperative to maintain and cleanse the copper interface between the flip chip and external circuit during and just prior to the bonding process. A common cleansing technique employed in the industry involves applying a “no-clean” flux, which serves to chemically eliminate copper oxides during the solder bonding procedure. Nonetheless, the chemicals and acids present in the flux pose a risk of corrosion, as residues can induce corrosion and electrical leakage at the bonded interface.

An alternative solution to the problem of copper oxidation during the bonding process involves soldering in (or immediately after treatment in) a formic acid and nitrogen environment. In this case, the copper oxides are dissolved by formic acid under heat applied in an oxygen-free environment. This solution works well to minimize contaminants left over at the interface after bonding. However, the formic acid reagent and bonding ovens/tools needed are highly engineered and expensive. As I/O density increases, improved process flows that provide high reliability at a low cost are needed for next-gen flip chip architectures and packaging.

### BRIEF SUMMARY OF THE INVENTION

The present invention provides techniques for minimizing defects (e.g., oxidation, corrosion, etc.) in flip chip packaging applications involving Cu pillar bonding. Non-limiting examples of flip chip packaging applications to which the disclosed techniques may be applied include flip chip Cu pillar solder cap to Cu substrate bonding. The disclosed bonding techniques enable Cu-to-solder bonding, such as Cu substrate to solder capped Cu pillar bonding (Cu-to-solder bonding) in flip-chip devices. The disclosed bonding techniques effectively address and reduce the oxidation issues commonly encountered in traditional bonding approaches.

According to aspects of the present disclosure, a substrate having copper features (e.g., features formed from Cu and Cu alloys) to be bonded to Cu pillars with solder caps may be cleaned (e.g., using a mildly acidic solution or dry etching technique) to remove surface oxides and contaminants. Once cleaned, the substrate may be rinsed (e.g., using water) and then provided to a coating unit where a protective coating is applied to the substrate. The protective coating may be applied by immersing the substrate in a bath, via chemical vapor deposition, or liquid coating processes. In an aspect, the protective coating may be copper selective so that the protective coating only adheres to or primarily adheres to the copper features of the substrate, such as copper bond pads, pillars, or other copper structures. The protective or passivation coating is designed to reduce the development of oxides and other factors that weaken bonds, which can occur during storage and, more critically, throughout bonding procedures. Eliminating or minimizing the extensive Cu oxidation that occurs during Cu-to-solder bonding in flip-chip packaging may significantly improve the quality of the bond between the two Cu features (e.g., solder capped Cu pillars and bond pads, lead frames, etc.) and may improve the reliability of the resulting bonded device(s). For example, a primary obstacle to achieving reliable Cu-to-solder bonding in flip-chip packaging is Cu's ambient and thermal-driven oxidation, which can generate oxides greater than 100 nm thick at the bonding temperature. This oxide layer prevents the joining of two Cu interfaces during solder reflow. By depositing a removable and ultrathin passivating film to protect the Cu surface from oxidation, the substrate may be maintained in a clean and oxide-free state for subsequent bonding to the next copper feature. In an aspect, an annealing process may be used to cure the protective coating and remove small imperfections and other abnormalities in the protective coating prior to the bonding process.

Using the techniques disclosed herein may facilitate reliable manufacturing of next generation packaging technology for automotive or other applications that require more robust, corrosion resistance and high conductivity connections (e.g., to reach required Automotive Electronics Council (AEC-Q100) grade 1, 0 safety standards). Thus, the techniques disclosed herein may improve the reliability of flip-chip bonded devices (e.g., by mitigating or minimizing formation of oxides at the Cu bond-site).

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawing, in which:

FIGS. 1A-1D are block diagrams illustrating different steps of a bonding process for bonding Cu pillars to metallic structures of a substrate in accordance with aspects of the present disclosure;

FIG. 2 is a block diagram illustrating an exemplary system for producing devices having metallic bonds in accordance with aspects of the present disclosure;

FIG. 3A shows images of a Cu surface with and without a protective coating applied in accordance with aspects of the present disclosure;

FIG. 3B is a graph illustrating oxide suppression achieved by applying the protective coating to the Cu surface of FIG. 3A in accordance with aspects of the present disclosure;

FIG. 4 illustrates a set of data analysis techniques that may be utilized to monitor and control the thickness of the passivation coating produced by the coating process in accordance with aspects of the present disclosure;

FIG. 5 is a graph illustrating an example of removing a portion of protective coating from the surface of a coated substrate using plasma etching in accordance with aspects of the present disclosure;

FIG. 6 is a diagram illustrating a micro-etching treatment for detecting localized coating defects or surface irregularities for different Cu surfaces and coating processes in accordance with aspects of the present disclosure;

FIG. 7 is a diagram illustrating an example process for fabrication of solder-bonded samples for pull testing in accordance with aspects of the present disclosure;

FIG. 8 is a flow diagram illustrating a process for testing coated-Cu to solder bonding in accordance with aspects of the present disclosure;

FIG. 9 is a Scanning Electron Microscope (SEM) of a mounted solder capped Cu pillar flip chip device onto a coated Cu substrate in accordance with aspects of the present disclosure;

FIG. 10 is a flow diagram of an exemplary method for mounting Cu to solder bonding in accordance with aspects of the present disclosure; and

FIG. 11 is a flow diagram of another exemplary method for performing Cu to solder bonding in accordance with aspects of the present disclosure.

It should be understood that the drawings are not necessarily to scale and that the disclosed embodiments are sometimes illustrated diagrammatically and in partial views. In certain instances, details which are not necessary for an understanding of the disclosed methods and apparatuses, or which render other details difficult to perceive may have been omitted. It should be understood, of course, that this disclosure is not limited to the particular embodiments illustrated herein.

### DETAILED DESCRIPTION OF THE INVENTION

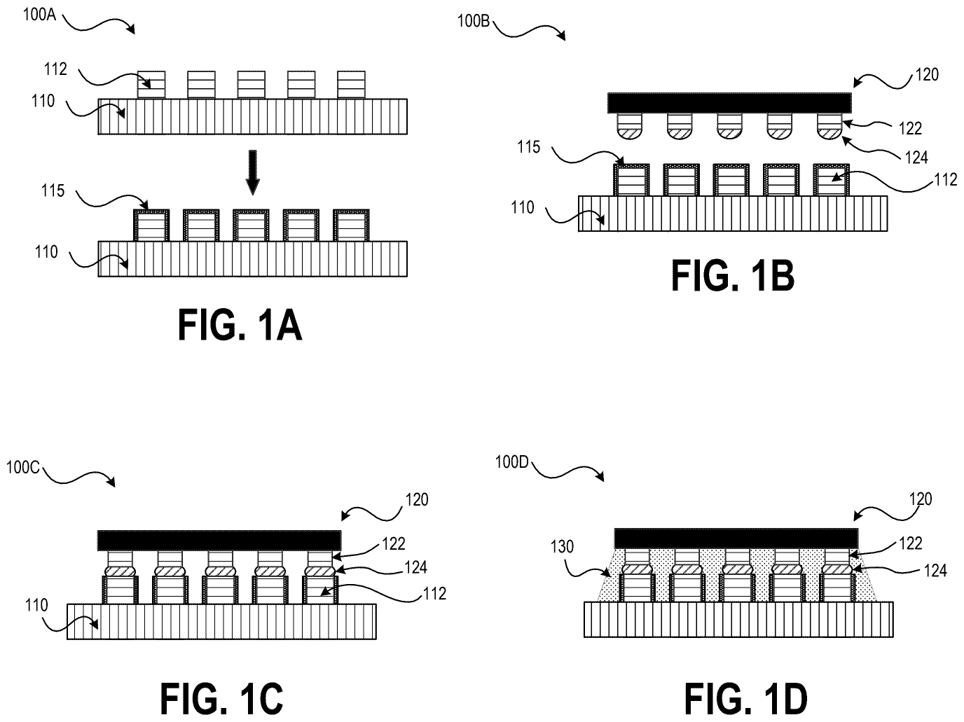

FIGS. 1A-1D are block diagrams illustrating different steps of a bonding process for bonding Cu pillars to metallic (e.g., made of Cu or Cu alloy) features of a substrate in accordance with aspects of the present disclosure. In FIGS. 1A-1D, a substrate 110 having metallic features 112 is shown. The substrate 110 may be a flexible substrate, a printed circuit board (PCB), or another type of substrate to which Cu pillars of a flip chip device may be bonded in accordance with the present disclosure. The metallic features 112 may correspond to metalized features, such as metal bonding pads or pillars, formed on the surface of the substrate 110. Such features may be positioned on the surface of the substrate 110 so as to align with matching Cu pillars of the flip chip device during the bonding process. In some embodiments, the metallic features 112 may be formed from Cu or Cu alloys on the surface of the substrate 110.

As shown in FIG. 1A, various metallic features 112 (e.g., Cu bond pad array, Cu trace substrate, Cu pillar, Cu carrier substrate, Cu tray, and the like) and other Cu features on the surface of substrate 110 (e.g., PCB-BT substrate, FR-4 organic substrate microfabricated interposer, another IC chip let, etc.) may be coated with a protective coating 115 during step 100A. In some embodiments, step 100A may correspond to an initial step of the bonding process in which the protective coating 115 is applied to the metallic features 112 on the substrate 110 before the remaining steps (e.g., steps 100B, 100C, and 100D of FIGS. 1B-1D) are performed. Alternatively, step 100A may correspond to a preliminary stage of flip chip mounting in which the coating process is performed by a vendor to mitigate or prevent oxidation and/or corrosion of the metallic features 112 and other features of the substrate 110 during storage (e.g., until the substrate is provided to a manufacturer who performs a bonding process in accordance with the present disclosure). For example, the coated substrate 110 in some implementations may need to be maintained in a storage facility for a period of time prior to the bonding process (corresponding to steps 100B, 100C, and 100D of FIGS. 1B-1D in this example), such as until the coated substrate can be delivered to a manufacturer who then bonds a flip chip device to the coated substrate in accordance with the concepts described herein. The protective coating 115 in either case may be designed to protect the substrate 110 before and during the bonding process, as will be described in further detail below. It is assumed, for purposes of the example substrate 110 shown in FIGS. 1A-1D and other substrate examples described below, that the metallic features or features of the substrate are Cu features (e.g., Cu pillars or bond pads) formed on the surface of the substrate. However, it is noted that substrate 110 could be another microfabricated chip let with Cu interconnect built in, or other PCB substrate (e.g., PCB-BT substrate, FR-4 organic substrate) having metallic features 112 formed of Cu and Cu alloy.

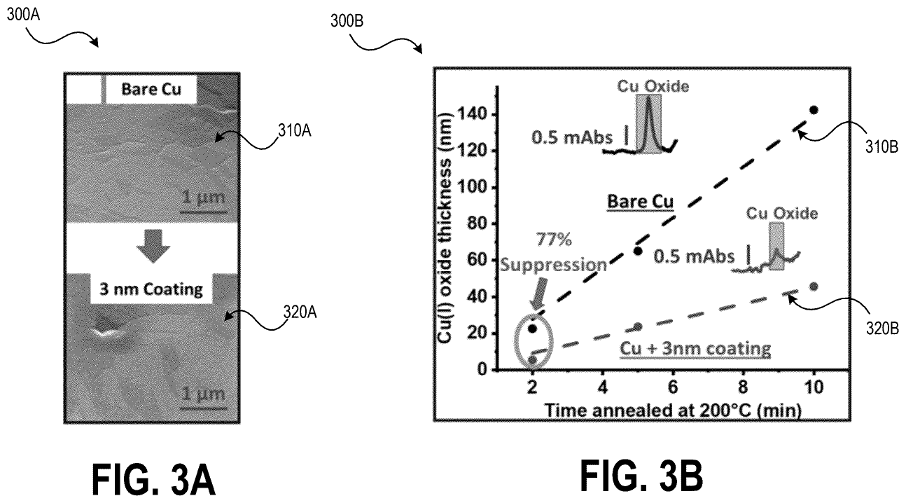

In some embodiments, the protective coating 115 applied at step 100A may be a Cu-selective passivation coating that is applied to the surface of the substrate 110 and the metallic features 112 to mitigate oxidation during the bonding process, as described above. Using a Cu selective protective coating 115 may ensure the protective coating 115 adheres to only the metallic features 112 and portions of the protective coating 115 applied to other portions of the substrate 110 may be removed, such as during a cleaning or rinsing process. Such a passivation coating may be, for example, a low-cost (e.g., less than $3.00 per 300-millimeter (mm) wafer) and ultrathin (e.g., less than 10 nanometer (nm)) coating that can be applied to the metallic features 112 on the substrate 110 using any of various dry or wet techniques compatible with wafer fabrication processing. As will be described in further detail below with reference to FIGS. 3A and 3B, such an ultrathin coating may be effective as an oxidation inhibitor that exhibits oxide suppression even at relatively high temperatures (e.g., at or above 230° C.), thus making it suitable for soldering processes and for preventing oxidation of metallic features 112 or other metallic features of the substrate(s) during storage. In contrast with conventional solder bonding processes, the protective coating 115 (e.g., Cu-selective passivation coating) applied to the metallic features 112 for the disclosed bonding process allows the underlying surface to be preserved and the reliability of the resulting flip-chip package to be improved without the corrosion risks associated with using a chemically-loaded “no-clean” flux or the high operating costs associated with using expensive formic acid equipment and reagents. Additionally, and as described below, the protective coating is not removed from the surface of the metallic features 112 prior to performing the bonding, such as bonding of a flip chip having metallic pillars to the metallic features 112.

As shown in step 100B of FIG. 1B, a bonding process according to aspects of the present disclosure may involve mounting a flip chip device 120 onto the substrate 110. The flip chip device 120 may be, for example, a semiconductor device or integrated circuit (IC) chip that can be mounted directly onto the substrate 110 after being flipped and appropriately positioned relative to the substrate 110 (e.g., metallic features of the flip chip device 120 are aligned with corresponding metallic features of the substrate 110). In some embodiments, the flip chip device 120 may be mounted to the substrate 110 by bonding Cu pillars 122 extending from the flip chip device 120 to the corresponding metallic features 112 (e.g., Cu bond pads, pillars, and the like) on the surface of the substrate 110. The ends of the Cu pillars 122 on the flip chip device 120 may include corresponding solder caps 124.

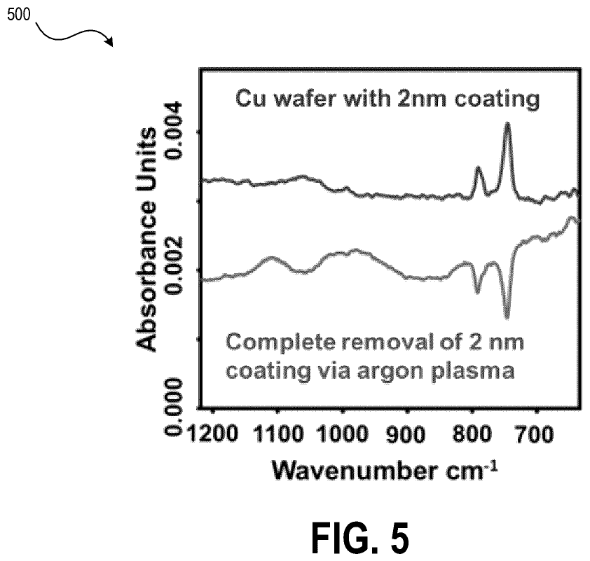

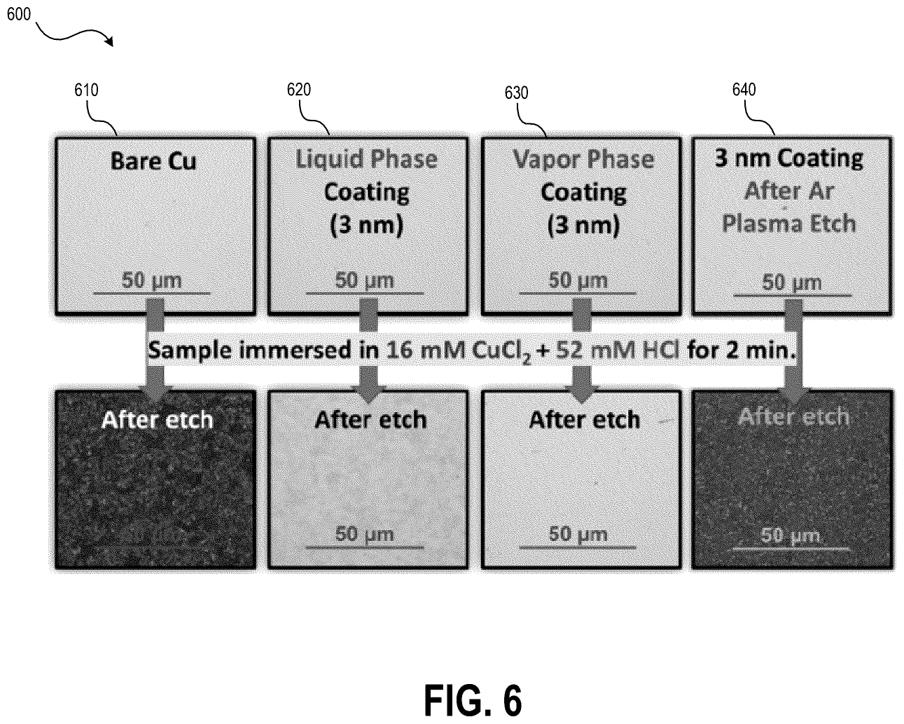

At step 100C shown in FIG. 1C, the solder caps 124 of the respective Cu pillars 122 may penetrate the protective coating 115 covering the metallic features 112 on the surface of the coated substrate 110 to bond directly with the metallic features 112. For example, the corresponding solder caps 124 at the ends of the Cu pillars 122 may be pressed into and through the coating 115, thereby making contact (e.g., electrical contact) with the metallic features 112 on the surface of the substrate 110. In an aspect, Cu pillars 122 may be bonded to metallic features 112 after the protective coating has been weakened or partially removed by plasma treatment. Such a plasma treatment may involve, for example, etching the surface of the coated substrate 110 with plasma to remove a portion (and reduce a thickness) of the protective coating covering the metallic features 112, as will be described in further detail below with reference to FIGS. 5 and 6. In either case, the protective coating 115 thickness will be made optimal for the bonding process, which minimizes the development of oxidation at the solder bonding interface between the Cu pillars 122 and the matching metallic features 112 on the surface of the substrate 110, thereby improving the strength of the bond formed between the flip chip device 120 and the substrate 110.

At step 100D shown in FIG. 1D, the bonding process in this example may include filling the open spaces between a surface of the flip chip device 120 and the substrate 110 with an underfill 130. The underfill 130 may be, for example, a non-conductive paste or other adhesive designed to protect the soldered connections between the metallic features 112 on the substrate 110 and the Cu pillars 122 of the flip chip device 120 surface from moisture, contaminants, and other environmental hazards. It should be appreciated that the underfill 130 may be composed of any suitable material as desired for a particular implementation. In some implementations, such material may be designed to mechanically lock the surface of the flip chip device 120 to the substrate 110 and thereby reduce any material stress or damage due to differences in thermal expansion between the substrate 110 and the flip chip device 120 over time.

It is to be appreciated that the advantages provided by aspects of the present disclosure are not realized solely based on the presence of the protective coating 115. Instead, the present disclosure provides innovative techniques to apply the protective coating 115 to metallic features 112 and eliminate defects present in the protective coating 115. Thus, it is to be appreciated that the disclosed protective coating 115 improves the manner in which the solder capped Cu pillar bonds to the substrate by enhancing the ability to mitigate Cu oxidation during the bonding process and storage, as will be described in more detail below.

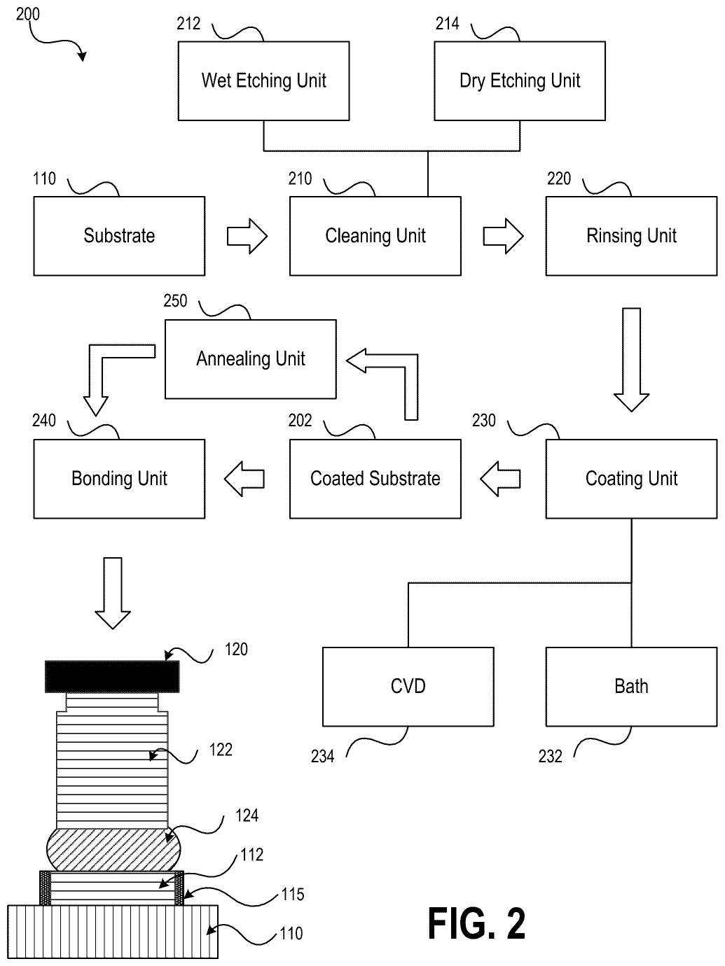

Referring to FIG. 2, a block diagram illustrating an exemplary system 200 for producing devices having metallic bonds under atmospheric conditions (e.g., an ambient air environment) in accordance with aspects of the present disclosure is shown. It is noted that FIG. 2 is described below with reference to flip-chip Cu pillar bonding applications involving a substrate. However, it should be understood that the concepts illustrated and described with reference to FIG. 2 may be performed with respect to metallic devices involving other forms of Cu pillar bonding applications. For example, the processes described with reference to FIG. 2 as being applied to a substrate may also be applied to Cu pillar bonded semiconductor devices (e.g., involving application of a protective or passivation coating to a surface of a silicon wafer), BGA (ball grid array) type of surface-mount packaging used for IC (integrated circuit), or other types of metallic devices (e.g., lead frames, etc.).

As shown in FIG. 2, system 200 may include a cleaning unit 210, a rinsing unit 220, a coating unit 230, and a bonding unit 240. The cleaning unit 210 may be configured to enable cleaning of a substrate, such as the substrate 110 of FIGS. 1A-1D. The cleaning unit 210 may include a wet etching unit 212, a dry etching unit 214, or both. The wet etching unit 212 may include a container, such as a plastic or glass container, that may be filled with a cleaning solution in which the substrate may be placed. While immersed in the cleaning solution bath, any contaminants and oxides present on the surface of the substrate may be removed by the cleaning solution. For example, the cleaning solution may be an acid and the substrate may be placed in the acid bath for a period to clean the surface of the substrate. In an aspect, the period in which the substrate is placed in the cleaning solution bath may be approximately 1 minute. In additional or alternative aspects, the period may be longer or shorter than 1 minute (e.g., 30 seconds(s), 40 s, 45 s, 50 s, 55 s, 30 to 55 s, 55 to 65 s, 65 to 85 s, 70 s, 80 s, 90 s, etc.). In an aspect, the acid used as the cleaning solution may be 3.5% sulfuric acid. In additional or alternative aspects, other formulations of sulfuric acid or another type of acid (e.g., acetic acid, hydrochloric acid, citric acid, other mild forms of acids, etc.) or cleaning solution may be utilized by the wet etching unit 212. The dry etching unit 214 may include an etching device configured to clean the surface of the metallic device(s) without the use of a cleaning solution, as is used by the wet etching unit 212. For example, the dry etching unit 214 may include a plasma etcher employing Ar, H₂, N₂, O₂, or mixtures thereof. The plasma etcher may treat the surface of the substrate (or other metallic device, or Cu wire bonded semiconductor devices) with plasma, thereby removing surface contaminants and oxides from the substrate. It is noted that plasma etching has been described herein for purposes of illustration, rather than by way of limitation, and that other etching techniques may be used by the dry etching unit 214 if desired (e.g., laser etching, etc.).

Once cleaned, the substrate may be provided to the rinsing unit 220. The rinsing unit 220 may be configured to rinse the cleaning solution off the substrate. The rinsing may be performed using deionized water or another rinsing agent. After rinsing is complete, the substrate may be provided to the coating unit 230, where a protective coating is applied. As shown in FIG. 2, the protective coating may be applied by the coating unit 230 in a variety of ways, including via a bath in a bath coating unit 232 or via chemical vapor deposition (CVD) in a CVD coating unit 234. The bath coating unit 232 may include a container (e.g., a glass or plastic container) and the protective coating may be applied by immersing the (cleaned and rinsed) substrate within a non-aqueous liquid bath. The non-aqueous liquid bath may include a solvent and one or more inhibitor compounds (i.e., the material providing the protective coating). The solvent may include ethanol, isopropanol, acetone, hexane, other solvents, or mixtures thereof (e.g., water and ethanol; water and isopropanol; acetone and hexane; water, acetone, and hexane; and so on). The one or more inhibitor compounds may be 5-mercapto-1-phenyl-tetrazole, 5-(4-methoxyphenyl)-2-amino1,3,4-thiadiazole, sulfathiazole, 5-amino1,3,4-thiadiazol 2-thiol, 1-phenyl-1H-tetrazole-5-thiol, 2-(2-dihydroxy-5-methyl)-phenyl-benzotriazole, 5-methyl-benzotriazole, amino tertiary butyl pyrazole, tetrazole, dodecane thiol, amino toluene, 1,2,4-triazole, cyproconazole, 4-(2-aminothiazol-4-yl)-phenol, 5-methyl-2-phenyl-2,4-dihydropyrazol-3-one, phenyl isothiocyanate; 4-methyl-5-imidazolecarbaldehyde, 5-(3-aminophenyl)-tetrazole, 2-amino-4-(4-chlorophenyl)-thiazole, 1-H-benzotriazole, 2-mercapto-benzoxazole, 5-methyl-benzotriazole, 5-methyl-benzimidazole, 2-mercapto benzimidazole, pyrazole, toly-triazole, 4-methyl-5-hydroxymethylimidazole, diniconazole, 4-(4-aminostyryl)-N,N-dimethylaniline, 8-methyl-benzotriazole, 3,5-diamino-1,2,4-triazole, phenyl urea, 5-(4-methoxyphenyl)-2-amino1,3,4-thiadiazole, 5-mercapto-1-phenyl-tetrazole, phenyl methyl benzotriazole, benzoxazole, other azole-based compounds, additional types of (non-azole compounds) compounds, or combinations thereof. In an aspect, the inhibitor compound(s) may be Cu selective such that when the substrate is immersed in the non-aqueous liquid bath provided by the bath coating unit 232, the inhibitor compound forms the protective coating on Cu components of the immersed substrate, such as Cu bonding pads, pillars, circuitry, wires, etc., and not to other portions of the substrate (e.g., a silicon wafer, ceramic substrate, a substrate formed form organic materials, and the like). In an alternative aspect, the bath used to apply the coating may utilize water (i.e., an aqueous bath), alone or in combination with other solvents (e.g., water and ethanol; water and isopropanol; water and acetone; water and hexane; water, acetone, and hexane; and so on). In an aspect, the bath may be heated. For example, the bath may be heated to a temperature in the range of 15° C. to 105° C. In some aspects, the bath may be heated to a temperature between 20° C. to 100° C., 25° C. to 100° C., 25° C. to 95° C., 30° C. to 90° C., 35° C. to 85° C., 35° C. to 90° C., 40° C. to 100° C., 40° C. to 90° C., or another within the range of 20° C. to 100° C. In some aspects, the bath may be heated to a temperature of approximately 60° C. In some aspects, the bath may be heated to a temperature between 50° C. to 90° C., 55° C. to 85° C., 60° C. to 80° C., 65° C. to 75° C., 68° C. to 72° C., 70° C. to 90° C., or 60° C. to 90° C. In some aspects, the bath may be mechanically stirred or agitated, such as by ultrasonic vibration, as a non-limiting example.

The CVD coating unit 234 may include a CVD chamber in which the substrate may be placed during application of the protective coating. To apply the protective coating the CVD chamber may be heated after the substrate is disposed therein and vapors of the one or more inhibitor compounds may be introduced into the CVD chamber. Alternatively, a quantity of the one or more inhibitor compounds may be placed in the CVD chamber with the substrate during the heating and as the heating occurs, the one or more inhibitor compounds may be vaporized, thereby releasing vaporized molecules of the one or more inhibitor compounds within the CVD chamber. In an aspect, the heating of the CVD chamber may be performed at temperatures in the range of 80° C. to 200° C. In an aspect, the heating of the CVD chamber may be performed at temperatures between approximately 90° C. and 110° C. The vaporized inhibitor compound may deposit on the surface of the substrate, thereby forming the protective coating or passivation layer on the substrate. In embodiments utilizing the CVD coating unit 234, the inhibitor compound may be the same inhibitor compound(s) described above with reference to the bath coating unit 232. Furthermore, the inhibitor compound may be Cu selective, thereby ensuring that the protective coating obtained through the CVD coating unit 234 is provided on Cu components (e.g., Cu bond pads, pillars, circuitry, wires, lead frame, etc.) rather than other portions of the substrate (e.g., a silicon wafer, etc.).

In an aspect, the temperature used to heat the CVD chamber may be configured to control characteristics of the protective coating being applied, properties or characteristics of the metallic device being coated (e.g., a Cu pillar, a substrate having Cu bond pads, a lead frame, etc.), or both. For example, certain temperatures may promote formation of ultrathin protective coatings while other temperatures may promote formation of thicker protective coatings. As another example, the metallic device placed within the CVD chamber may be heated during the heating of the CVD chamber, which may alter properties or characteristics of the surface of the metallic device (e.g., heating at certain temperatures may promote or cause oxidation of Cu metallic devices, such as Cu pillars or bond pads of a substrate). As such, the heating of the CVD chamber may be controlled to mitigate the occurrence of undesirable changes in the properties or characteristics of the metallic device(s) and to promote formation of a protective coating of a desired thickness.

In an aspect, the coated substrate may be rinsed following immersion in the bath coating unit 232 or deposition via the CVD coating unit 234. Rinsing the coated substrate may remove excess inhibitor compound(s) from the surface of the substrate. In an aspect, the rinsing may be performed using the same or a similar solvent to the solvents described above with reference to the bath coating unit 232.

As a result of the operations of the coating unit 230 (e.g., the bath coating unit 232 or the CVD coating unit 232), a protective coating may be deposited on a surface of the substrate to produce a coated substrate 202 (e.g., the protective coating 115 deposited on a surface of the substrate 110 prior to bonding the metallic features 112 on the surface with solder caps 124 of the Cu pillars 122 extending from the flip chip device 120 of FIGS. 1A-1D, as described above). The protective coating may range in thickness between 1 nanometer (nm) to 100 nm. In an aspect, the protective coating may have a thickness between 1 nm to 3 nm, 2 nm to 10 nm, 10 nm to 20 nm, 20 nm to 50 nm, 50 nm to 100 nm, or combinations thereof. It is noted that the various exemplary thickness ranges described above have been provided for purposes of illustration, rather than by way of limitation. As described above, the system 200 of FIG. 2 provides functionality that may enable the thickness of the protective coating to be controlled, allowing thicker protective coatings or thinner protective coatings to be produced depending on the particular Cu bonding application involved and whether the particular Cu bonding application would benefit from a particular thickness of the protective coating.

As described above, when a Cu-selective inhibitor compound(s) is utilized, the protective coating may be provided on Cu features of the substrate (e.g., Cu pillars, bond pads, circuitry, wires, lead frame, etc.) while non-Cu portions of the substrate (e.g., silicon) may be unaffected by the protective coating. Utilizing the above-described techniques (e.g., the bath or CVD) to apply one or more inhibitor compounds and form the protective coating is advantageous as compared to other possible application techniques. For example, it is possible to brush or roll on protective coatings, but the brushing technique results in the protective coating being deposited on the entire surface of the substrate, rather than just the Cu components or structures. Additionally, the brush or roll-on application methods also tend to lead to a non-uniform coating (e.g., in terms of thickness). In contrast, the bath and CVD methods disclosed herein can provide conformal coating around various complicated geometries, with potentially only 5-10% thickness variation. An additional advantage provided by the bath method described above with reference to bath unit 232 is the use of non-aqueous solvents, which eliminate the potential for residual moisture to be trapped within the packaging of the final product. However, as noted above, aqueous bath solutions may also be used to apply the one or more inhibitor compounds in some implementations.

After the coated substrate 202 is produced it may be provided to a bonding unit 240. The bonding unit 240 may be configured to perform bonding of two or more Cu devices, such as bonding of solder capped Cu pillars (e.g., Cu pillars 122 of FIGS. 1B-1D) to Cu bond pads (or other metallic features) of the coated substrate 202. As described above with reference to FIGS. 1A-1D, the Cu-to-solder bonding enabled by protective coatings applied to the substrate (e.g., in accordance with the above-described features of the system 200 of FIG. 2) may minimize or mitigate oxidation and enhance inter-metallic formation at the bonding site, thereby yielding a better bond (e.g., better electrical conductivity and bond strength) between the two Cu devices (e.g., Cu, Cu alloy, or coated Cu devices). As will be described in more detail below, bonding processes performed in accordance with the concepts described with reference to the system 200 of FIG. 2 result in greater success in Cu substrate to solder capped Cu pillar bonding, thereby enabling next generation chips and devices satisfying parts per billion (ppb) failure requirements to be realized.

In some aspects, the system 200 may include an annealing unit 250. The annealing unit 250 may be configured to anneal the coated substrate 202 (e.g., prior to performing a bonding process). For example, the annealing unit 250 may heat the coated substrate 202 to a desired temperature (e.g., a temperature between 100-260° C.). The annealing may be performed in a desired environment, such as air (e.g., via either convection-style or static oven heating), under vacuum (e.g., 1×10⁻⁹ Torr to 1 Torr), or under an inert gas (e.g., nitrogen, argon, forming gas—95/5 nitrogen-hydrogen mixture), as non-limiting examples. The annealing of the coated substrate 202 may remove minor imperfections or other defects in the applied coating, thereby improving the protection against oxidation and degradation of the bonds formed during bonding at the bonding unit 240.

In an aspect, substrates, and other metallic devices (e.g., Cu pillars, Cu bond pads, lead frames, etc.) processed using the system 200 may be maintained in a “wet” state prior to applying the protective coating at the coating unit 230. To maintain the substrates in the “wet” state prior to coating, the substrate(s) 110 or portions thereof may be placed in a container of water following cleaning via cleaning unit 210 and transported to the rinsing unit 220 in the container of water. Once rinsed, the substrate may be placed in the same or new (clean) container of water for transport to the coating unit 230. At the coating unit 230, the cleaned and rinsed substrate may be removed and provided to the coating unit 210 for coating (e.g., via bath coating unit 232 or CVD coating unit 234), as described above. In an additional or alternative aspect, the substrate may be misted with water during transport between the cleaning unit 210, the rinsing unit 220, and the coating unit 230, rather than being placed in a water bath. Maintaining the substrate in the “wet” state after cleaning and prior to application of the protective coating may minimize the development of surface oxides or other contaminants on the substrate and may improve the adhesion or deposition of the protective coating to the Cu components of the substrate.

Using the processes described above with reference to the system 200 of FIG. 2 enables bonding of metallic features of a substrate to solder capped Cu pillar bonding to be formed in a reliable manner since the inhibitor compound(s) used to provide the protective coating eliminates oxidation at the bonding site(s). Moreover, since the inhibitor compound(s) may be Cu-selective, the substrate is not coated with excess material, minimizing the impact of the protective coating on the substrate or other components and features. The disclosed techniques also provide a low cost and fast coating process that is compatible with Cu chemical and mechanical planarization (CMP) process and microelectronic wafer fabrication processing flow. For example, the disclosed coating process can be performed at low-cost (e.g., less than $0.01 per die) when applied in the whole wafer batch process. The disclosed Cu-selective coating process also minimizes or eliminates wafer warpage that may be caused by other blanket coating techniques. Moreover, the coating process enhances packaging reliability and enables more reliable use of Cu substrate to solder capped Cu pillar bonded devices.

Referring to FIG. 3A, scanning electron microscope (SEM) images of a Cu surface 300A are shown, where an image 310A shows the Cu surface 300A without any protective coating applied and an image 320A shows the Cu surface 300A with a protective coating applied in accordance with embodiments of the present disclosure. It is assumed for purposes of this example that the protective coating applied to the coated Cu surface 300A shown in image 320A is an ultrathin Cu-selective passivation coating having a thickness of only 3 nm. As can be seen in image 320A, the passivated Cu surface shows visible grain structures, which indicate that the protective coating is conformal over the Cu surface. Thus, image 320A in FIG. 3A illustrates that the coating techniques disclosed herein may be used to provide a uniform application of the protective coating (e.g., the one or more inhibitor compounds) on Cu surfaces.

Referring to FIG. 3B, a graph 300B illustrates the level of oxide suppression that can be achieved with the protective coating under elevated temperature annealing (e.g., as performed by the annealing unit 250 of FIG. 2, as described above) in accordance with aspects of the present disclosure. In FIG. 3B, a trendline 310B represents the level of Cu oxidation associated with the bare or untreated Cu surface 300A (from the image 310A of FIG. 3A) and a trendline 320B of the graph 300B represents the level of Cu oxidation associated with the coated Cu surface 300A (from the image 320A of FIG. 3A). As described above, it is assumed for purposes of this example that the protective coating applied to the coated Cu represented by the trendline 320B is approximately 3 nm thick. It is also assumed for purposes of this example that the data used to calculate the trendlines 310B and 320B in the graph 300B of FIG. 3B was obtained during annealing of the respective unprotected and protected Cu surfaces at 200° C., which is near the temperatures common to bonding processes used for solder bonding Cu pillars and flip chip devices. A comparison of the trendlines 310B and 320B in the graph 300B demonstrates that even an ultrathin (3 nm) protective coating applied to the Cu surface in this example can suppress 77% more oxidation within the first two minutes of annealing at 200° C. than the bare Cu surface alone can in the same period of time. Furthermore, thicker passivation coatings (15-40 nm) also show over 64% suppression of Cu oxidation when heated at higher temperatures (e.g., 230° C.) common to bonding processes used for solder bonding Cu pillars and flip chip devices.

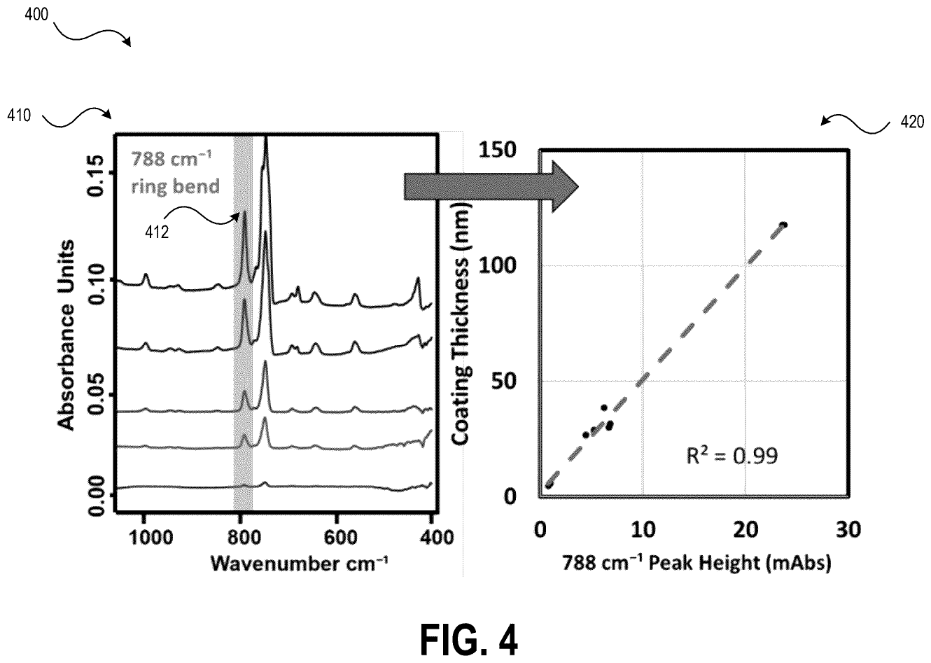

To achieve an ultra-thin (e.g., 2-5 nm) passivation coating that is effective to suppress Cu oxide formation under elevated temperature annealing, the coating chemistry and deposition conditions may need to be monitored and controlled during the coating process. In some embodiments, one or more data analysis techniques, such as Reflection-Absorption Infrared Spectroscopy (RAIRS) and quartz crystal microbalance (QCM) may be used be used to characterize the Cu thermal oxidation under solder and reflow conditions (e.g., at 220-260° C.) and evaluate the effectiveness of different thickness levels of the applied coating to suppress Cu oxidation. These techniques may be used to selectively monitor and control the coating thickness by changing the coating chemistry and deposition conditions (e.g., deposition time, temperature, concentration of inhibitor compounds, etc.) to optimize the coating process, as will be described in further detail below with reference to FIG. 4.

In FIG. 4, a set of graphs 400 is shown to illustrate the results of RAIRS spectra analysis (graph 410) and correlated QCM data (graph 420) for different thicknesses of protective coating applied to a Cu surface (e.g., a surface of a Cu wafer or substrate). In some embodiments, the spectra analysis may be based, at least in part, on measurements acquired by a RAIRS probing tool during the coating process. Such a RAIRS tool may be capable of detecting fractional monolayer changes on metal surfaces. For example, the sensitivity of the RAIRS tool and spectra analysis may be sufficient to detect an infrared (IR) absorption peak change of 0.0002 absorbance unit. As shown in FIG. 4, the RAIRS spectra represented by a portion 412 of the graph 410 exhibits a steady increase of specific chemical bonding at 788 cm⁻¹, which suggests that a thickness of the passivation coating can be readily controlled with changes to the coating chemistry and deposition conditions. Additionally, the QCM data as shown in graph 420 may be used to quantify the mass or thickness of the coating that directly correlates to the 788 cm⁻¹ peak height of the RAIRS spectra. Accordingly, RAIRS spectra analysis may be used as a powerful characterization tool to quantify and monitor coating thickness and oxidation levels on the Cu surface, enabling oxidation suppression to be optimized during the coating process. As solder unwettability of Cu arises from the continual growth of non-passivating Cu oxides, the application of the protective coating to the Cu surface may serve as an effective strategy to protect the Cu surface from thermal oxide growth. The growth behavior of thermal Cu oxide under soldering conditions (e.g., at temperatures over 220° C.) may be first characterized by RAIRS metrology to establish a baseline. Importantly, Cu oxide growth inhibition provided by the passivation coating, as measured by the RAIRS probing tool and spectra analysis, may be used as a guide to determine appropriate changes that may be needed to optimize the coating process. Such changes may include, for example, adjustments to one or more of the coating chemistry, deposition time, temperature, concentration, additives, and pretreatments. For protective coatings applied using CVD (e.g., by the CVD coating unit 234 of FIG. 2), as described above, adjustments may be made to one or more of the pre-heating temperature, precursor loading, carrier gases, CVD temperature and deposition time, sample placement configuration and oven heating conditions (for static or convection heating).

In some embodiments, the measurements from the RAIRS probing tool may be utilized to select passivation coatings that form strong covalent bonding on the Cu surface. In addition, one or more plasma etching treatments (e.g., using Ar, Ar/H₂ plasma) may be used to pre-treat the passivation films to facilitate strong solder bonding. Such plasma treatments may be used to tune the chemical bonding of ultra-thin passivation coatings on Cu substrates (e.g., by partially weakening or removing a portion of the coating (e.g., 2 nm) from a coated Cu surface (e.g., with a 20 nm coating) to appropriately match the needs of the solder bonding process and/or testing protocols used to test solder bonding strength.

FIG. 5 is a graph 500 illustrating the results of removing a portion of the protective coating from the surface of a coated substrate using plasma etching in accordance with aspects of the present disclosure. As shown in FIG. 5, the results illustrated by the graph 500 demonstrate that the complete removal of a 2 nm coating from a Cu surface can be achieved by Ar plasma etching without adding significant amount of Cu oxide, e.g., as verified by measurements from a RAIRS probe. These results may be further validated by using one or more sensitive surface analytical techniques, such as QCM, SEM/EDS, XPS, AFM, and FIB-SEM. As the information gathered by the RAIRS probe is specific to chemical bonding changes on the Cu surface, the RAIRS data may also be suitable for detecting any decomposed and oxidized coating artifacts that may be produced during the coating process as well as for determining the upper limit of a protective coating's thermal stability in various environments with and without the presence of oxygen.

As described above, the coating techniques disclosed herein may be used to provide a uniform application of the protective coating on Cu surfaces. The uniformity of the passivation coating may be an important factor that needs to be controlled during the coating process to enable flux-less, low-cost Cu flip chip bonding in accordance with aspects of the present disclosure. While RAIRS is useful for detecting an average of the coating thickness changes across an area of a Cu surface or sample, it may not provide information on localized coating defects and inhomogeneities. Therefore, in some embodiments, a “micro-etching” technique may be used to supplement RAIRS and expose any defects or weak spots after the coating process, as will be described with respect to FIG. 6.

FIG. 6 is a diagram illustrating a micro-etching treatment 600 for detecting localized coating defects or surface irregularities for different coating processes in accordance with aspects of the present disclosure. In some embodiments, the micro-etching treatment 600 applied to each surface in this example may involve intentionally attacking the Cu surface with a roughening oxidative etchant that quickly corrodes any exposed Cu, thereby highlighting any regions of nonuniformity or coating defects on the Cu surface. As shown in FIG. 6, bare Cu surface 610 with no coating after the micro-etching treatment oxidized the Cu and may be used to detect any defects or weak spots across coated Cu surfaces which can be either after a liquid (or wet) coating process 620 or after a vapor (or dry) coating process 630. In addition, a coated Cu surface 640 after a plasma etching treatment (e.g., using Ar plasma) showed similar results such as bare copper which confirms the removal of coating. While the thickness of the coating for each of the coated Cu surfaces 620, 630, and 640 is shown in FIG. 6 as 3 nm, it should be appreciated that embodiments of the present disclosure are not intended to be limited thereto and that these techniques may be applied to any coating thickness between 1 nm and 200 nm (or other desired thickness range, as described above). However, as shown in FIG. 6, such a Cu specific etchant has no effect on ultrathin (e.g., 3 nm) passivation coatings applied to either the surface 620 using the liquid/wet coating process or the surface 630 using the vapor/dry coating process. Also, as shown in FIG. 6, the micro-etching treatment 600 may be used to verify that the coating applied to surfaces 620 and 630 using wet and dry coating processes, respectively, is uniform and that the protection is removed, at least partially, from the surface 640 after the Argon plasma etching treatment. Accordingly, data from the micro-etching treatment 600 may be used to verify the tunable “on-off” nature of the coating as shown by the Cu etching after the plasma removal treatment applied to the surface 640. This data demonstrates that the ability to partially remove and modify a few nanometers of passivation coating on Cu substrate enables fine tuning of passivation coating to optimize the Cu substrate to solder capped Cu pillar bonding strength.

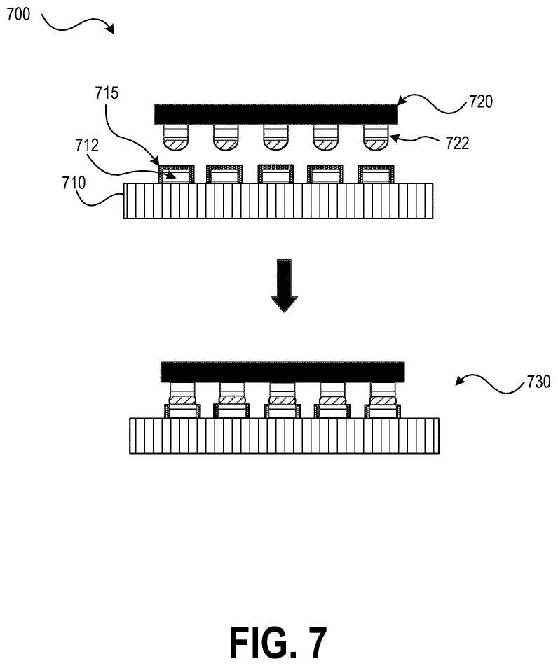

In addition to the coating optimization techniques described above, various pull-test or pull-strength testing techniques may be used to evaluate solder bonding strength in Cu pillar bonding structures. For example, a pull-test setup may be validated by preparing maximum and minimum strength Cu solder bonded samples. The maximum strength samples may be fabricated by preparing freshly sputtered Cu and bonding in an oxygen-free formic acid/nitrogen environment. The minimum strength samples may be prepared by solder bonding on air-oxidized Cu substrate, as shown in FIG. 7.

FIG. 7 is a diagram illustrating an example process 700 for the fabrication of Cu to solder bonded samples for pull testing in accordance with aspects of the present disclosure. As shown in FIG. 7, process 700 may involve bonding a coated Cu substrate layer 712 on a silicon wafer 710 to solder-capped Cu pillars 722 extending from a flip chip device 720. For example, the solder-capped Cu pillars 722 may be pressed onto and through a blanket of protective coating 715 on the surface of the Cu substrate 712 to bond directly with the underlying Cu substrate 712 under solder bonding temperatures to produce a solder-bonded sample 730, as shown in FIG. 7.

After completion of the device bonding and solder reflow, the sample 730 and other samples that are similarly produced may be transferred for conducting a solder ball pull test. The reliability of the testing may be monitored with a digital Newton meter with fine pull rate control (e.g., with a pull speed of less than 60 mm/min for 100 solder bonds per sample). For example, the samples may be used to test the effectiveness of three types of bonding conditions or scenarios: (1) bare Cu in a formic acid/nitrogen environment (generally associated with good bonding strength); (2) bare Cu in air environment (bonding strength is expected to be poor, as thermal oxides generally weaken/disable solderability); and (3) Cu protected using the disclosed passivation coating techniques in an ambient air environment, which is intended to produce a coated-Cu substrate to solder capped Cu pillar bonding strength that is comparable to the bare Cu in formic acid environment (in the first scenario).

The pull strength of the three bonding scenarios listed above may be compared to evaluate effectiveness of the passivation processes. Each individual wafer and bonded chip may be fixed by an epoxy or super glue adhesion to the instrument base and an aluminum pull stud, respectively, to carry out pull testing. According to MIL-STD-833 method 2031.1 by the Department of Defense, the bonded solder capped Cu pillar with a coated Cu substrate exhibits a tensile pull strength within the range of 42 to 132 Newtons. Post pull testing, FIB-SEM cross-sectional analysis on the bonding interfaces may also be conducted to compare the Cu/solder interfaces for formation of intermetallic, or remaining passivation layer. The overall aim of such testing may be to achieve a comparable bonding strength to the formic acid/nitrogen atmosphere bonding or any Cu-pillar area bonding strength that may be standardized or desired for a particular flip-chip packaging application. Accordingly, the results of the pull-strength testing performed with the samples produced from process 700 may be utilized to evaluate and optimize the strength of the coating-assisted Cu pillar solder bonds produced using both mass reflow and thermocompression bonding techniques in accordance with aspects of the present disclosure. For example, the testing results may be used in the disclosed solder bonding techniques to optimize coating conditions, minimize coating defects to suppress Cu oxidation, develop an appropriate process flow for achieving solder bonding assisted by the coating, and apply the optimized coating and process flow to flip chip devices.

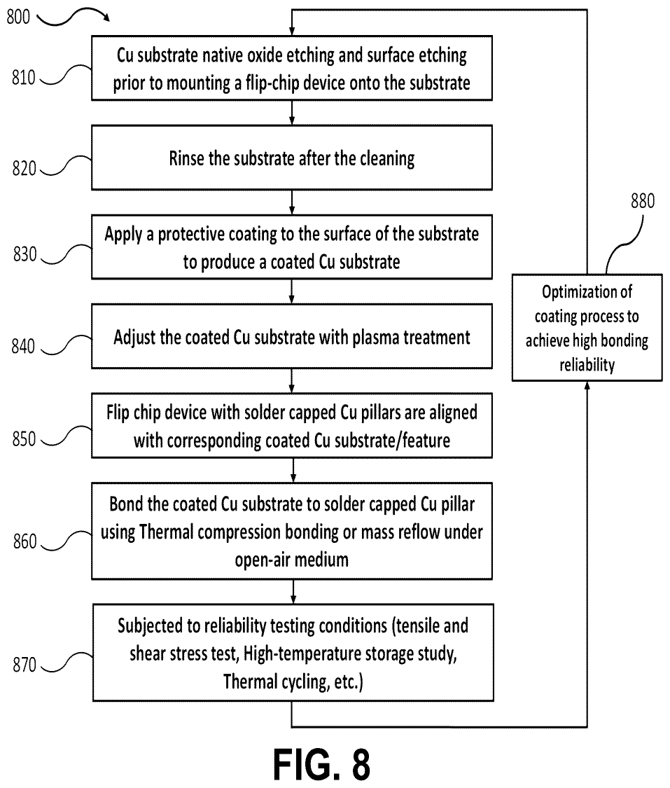

FIG. 8 is a flow diagram of an exemplary method 800 for mounting flip chip devices onto a substrate in accordance with aspects of the present disclosure. In an aspect, the method 800 may be performed using a system, such as the system 200 of FIG. 2, as described above. At step 810, the method 800 includes cleaning a surface of a substrate prior to mounting a flip chip device onto the substrate. The surface of the substrate may be cleaned to remove surface oxides, contaminates, or both. As described above with reference to FIG. 2, the cleaning may be performed by immersing the substrate (or metallic features on the surface of the substrate) in a cleaning solution maintained in a container of a cleaning unit (e.g., the wet etching unit 212 of FIG. 2). The cleaning solution may include an acid, such as acidic solutions formed using sulfuric acid, acetic acid, hydrochloric acid, nitric acid, or other mildly acidic solutions. As described above, the cleaning may be performed by immersing the substrate in the cleaning solution for a period of time (e.g., approximately 1 minute). Alternatively, the cleaning may be performed in the absence of a cleaning solution, such as by the dry etching unit 214 of FIG. 2. For instance, the substrate, along with any accompanying metallic features, can undergo cleaning treatment via a plasma etcher or alternative “dry” etching techniques to eliminate surface oxides, contaminants, and similar impurities. At step 820, the method 800 includes rinsing the substrate after the cleaning/etching. In an aspect, the rinsing may be performed using a rinsing unit (e.g., the rinsing unit 220 of FIG. 2) and the rinsing of the substrate may utilize water or another rinsing agent to remove any cleaning solution or particles removed by the dry etching that remain present on the substrate after the cleaning.

At step 830, the method 800 includes applying a protective coating to the surface of the substrate to produce a coated substrate. In some embodiments, the protective coating is applied after the rinsing (at step 820) by immersing the substrate in a solution comprising a solvent and one or more inhibitor compounds, where the protective coating may be formed from the one or more inhibitor compounds. As described above with reference to FIG. 2, the coating unit (e.g., the coating unit 230 of FIG. 2) may be configured to apply a protective coating to at least a portion of the substrate. For example, the protective coating may be Cu selective such that the portion of the substrate covered by the protective coating corresponds to at least one or more copper features of the substrate, such as bond pads or other copper features. The protective coating applied to the substrate at step 830 may include one or more inhibitor compounds, such as 5-mercapto-1-phenyl-tetrazole, 5-(4-methoxyphenyl)-2-amino1,3,4-thiadiazole, sulfathiazole, 5-amino1,3,4-thiadiazol 2-thiol, 1-phenyl-1H-tetrazole-5-thiol, 2-(2-dihydroxy-5-methyl)-phenyl-benzotriazole, 5-methyl-benzotriazole, amino tertiary butyl pyrazole, tetrazole, dodecane thiol, amino toluene, 1,2,4-triazole, cyproconazole, 4-(2-aminothiazol-4-yl)-phenol, 5-methyl-2-phenyl-2,4-dihydropyrazol-3-one, phenyl isothiocyanate; 4-methyl-5-imidazolecarbaldehyde, 5-(3-aminophenyl)-tetrazole, 2-amino-4-(4-chlorophenyl)-thiazole, 1-H-benzotriazole, 2-mercapto-benzoxazole, 5-methyl-benzotriazole, 5-methyl-benzimidazole, 2-mercapto benzimidazole, pyrazole, toly-triazole, 4-methyl-5-hydroxymethylimidazole, diniconazole, 4-(4-aminostyryl)-N,N-dimethylaniline, 8-methyl-benzotriazole, 3,5-diamino-1,2,4-triazole, phenyl urea, 5-(4-methoxyphenyl)-2-amino1,3,4-thiadiazole, 5-mercapto-1-phenyl-tetrazole, phenyl methyl benzotriazole, benzoxazole, other azole-based and non-azole-based compounds, or combinations thereof. As described above with reference to FIG. 2, the protective coating may be copper-selective such that the coating adheres to the one or more copper features of the substrate and any portions of the protective coating not adhered to the copper feature(s) may be removed. In one aspect, one substrate could undergo a secondary rinsing process after the application of the protective coating, aimed at eliminating any physiosorbed coating material, such as the inhibitor compounds described above with FIG. 2. As described above with reference to FIG. 2, the coating unit may be a bath coating unit (e.g., the bath coating unit 232 of FIG. 2) or a CVD coating unit (e.g., the CVD coating unit 234 of FIG. 2). In some aspects the substrate may be maintained in a wet state in between steps 810, 820, 830 as described above with reference to FIG. 2.

In some embodiments, step 830 of the method 800 may include annealing the substrate after applying the protective coating. As described above, annealing may mitigate or remove minor imperfections in the protective coating after its application. In an aspect, the substrate is maintained in a storage facility for a period of time prior to the bonding. By using the protective coating one or more copper features of the substrate may be prevented from developing oxides or other negative artifacts that may reduce the quality of subsequent bonding processes, thereby improving the quality of any subsequently formed bonds. At step 840 of the method 800, the procedure involves surface modification and the thickness adjustment of coating on Cu metallic feature on substrate using plasma treatment, this adjustment aims to enhance the solder wetting performance on the coated Cu metallic feature on substrate during the bonding process illustrated in FIG. 7.

At step 850 of method 800, this procedure involves precise alignment of the solder capped Cu pillar flip chip devices onto the corresponding Cu structure on substrates prior to initiating the bonding process. After the alignment process in step 850 of method 800, step 860 depicts the bonding procedure, wherein solder capped Cu pillar flip chip devices are bonded onto the coated Cu structure on substrates, this bonding process can be executed using either Thermal Compression Bonding (TCB) or Mass Reflow (MR) bonding techniques in open-air environment. Each of these bonding processes entails distinct bonding profiles, characterized by bonding temperatures ranging from 240° C. to 300° C. and bonding times spanning 1 to 5 minutes. Specifically, Thermal Compression Bonding (TCB) incorporates varying bonding pressures tailored to the solder capped Cu pillar flip chip samples being processed. In step 870 of method 800, the flip chip device bonded onto the coated Cu substrate undergoes rigorous package reliability testing procedures. These include mechanical tests such as tensile pull and shear stress assessments for measuring pull strength, as well as high temperature storage studies and thermal cycling analyses after adding under-fill to increase mechanical stability. Reliability tests are aimed at evaluating solder wetting characteristics and solder breaking points.

Step 880 of method 800 encompasses the optimization process, wherein adjustments are made based on the finding derived from steps 860 to 870. These optimization efforts pertain to both the coating and bonding processes. Such structural resiliency may improve the lifespan of devices and reduce failure rates, thereby enabling the benefits of coated-Cu substrate to solder capped Cu pillar bonds to be utilized in certain environments, such as automotive applications, where bonded devices may be subject to harsh and corrosive environments. As shown above, the bonding process described above with respect to method 800 and system 200 provide a chemistry-driven approach to selectively protect Cu contact features from oxidation via a wide selection of processes. Such capabilities enable low temperature vapor phase application of protective coatings for dry processes (e.g. for IC chip designs having features that can be damaged from liquid immersion). Additionally, unlike volatile inhibitors, the inhibitor compound(s) used to apply protective coatings in accordance with the concepts disclosed herein remain intact and bonded on Cu surfaces even in ambient conditions, making it ideal for situations where the substrates may require storage prior to performing bonding processes. Additionally, as described above, the techniques disclosed herein may also enable selective control of coating thickness, such as by changing process conditions (e.g., exposure time, temperature, concentration of inhibitor compounds, etc.).

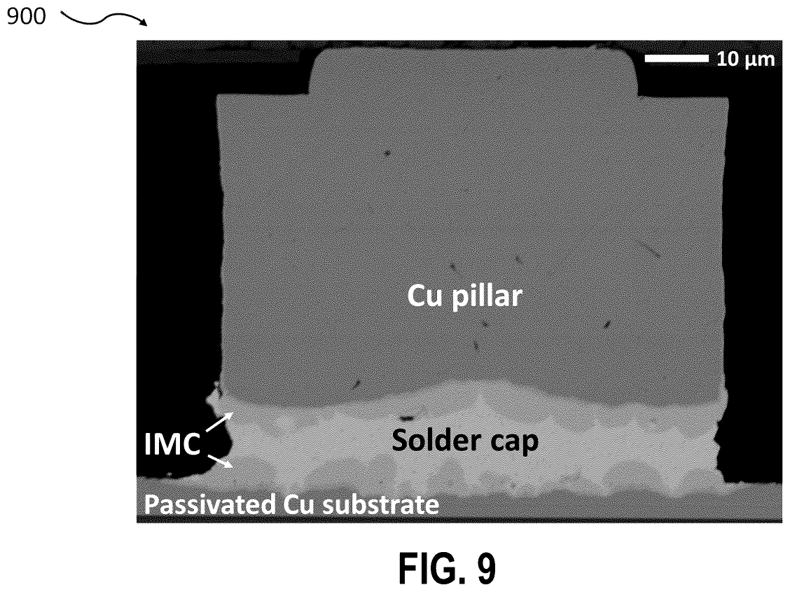

FIG. 9 presents a Scanning Electron Microscope (SEM) image, denoted as 900, illustrating the solder capped Cu pillar flip chip device bonded onto the coated Cu substrate via method 800. This cross-section SEM image reveals clear solder wetting phenomenon, indicating strong bonding between the solder capped Cu pillar of flip chip and the coated Cu substrate in open air. SEM image 900 shows clear formations of intermetallic compounds (IMCs) such as Cu₆Sn₅ and Cu₃Sn that create a strong bond between solder cap and coated Cu substrate without the disabling thermal oxide interference usually formed at the elevated bonding temperature. This SEM image evidence underscores the effectiveness of the applied coating techniques on the Cu substrate surface, facilitating the solder wetting and the formation of clear IMCs at the interface under the open-air ambient environment.

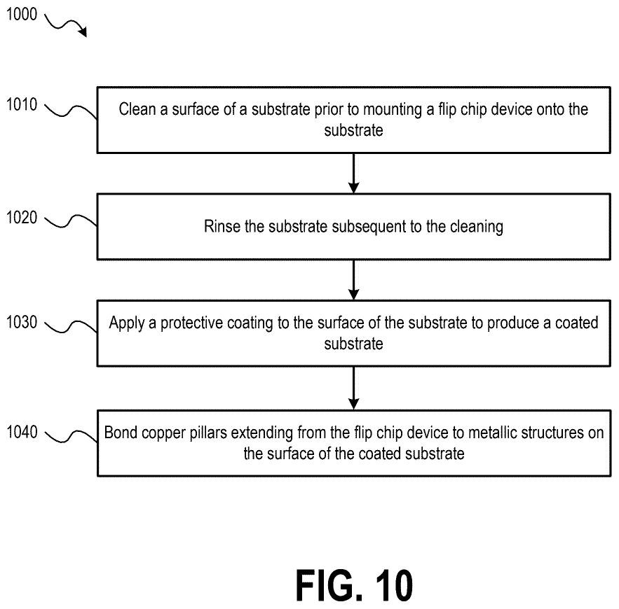

FIG. 10 is a flow diagram of an exemplary method 1000 for performing Cu to solder bonding in accordance with aspects of the present disclosure. In an aspect, the method 1000 may be performed using a system, such as the system 200 of FIG. 2, as described above. At step 1010, the method 1000 includes cleaning a surface of a substrate prior to mounting a flip chip device onto the substrate. The surface of the substrate may be cleaned to remove surface oxides, contaminates, or both. As described above with reference to FIG. 2, the cleaning may be performed by immersing the substrate (or metallic features on the surface of the substrate) in a cleaning solution maintained in a container of a cleaning unit (e.g., the wet etching unit 212 of FIG. 2). The cleaning solution may include an acid, such as acidic solutions formed using sulfuric acid, acetic acid, HCl, citric acid, or other mildly acidic solutions. As described above, the cleaning may be performed by immersing the substrate in the cleaning solution for a period (e.g., approximately 1 minute). Alternatively, the cleaning may be performed in the absence of a cleaning solution, such as by the dry etching unit 214 of FIG. 2. For example, the substrate (or other metallic features thereon) may be treated by a plasma etcher or another form of “dry” etching to remove surface oxides, contaminates, etc. At step 1020, the method 1000 includes rinsing the substrate subsequent to the cleaning. In an aspect, the rinsing may be performed using a rinsing unit (e.g., the rinsing unit 220 of FIG. 2) and the rinsing of the substrate may utilize water to remove any cleaning solution or particles removed by the dry etching that remain present on the substrate after the cleaning.

At step 1030, the method 1000 includes applying a protective coating to the surface of the substrate to produce a coated substrate. In some embodiments, the protective coating is applied subsequent to the rinsing (at step 1020) by immersing the substrate in a solution comprising a solvent and one or more inhibitor compounds, where the protective coating may be formed from the one or more inhibitor compounds. As described above with reference to FIG. 2, the coating unit (e.g., the coating unit 230 of FIG. 2) may be configured to apply a protective coating to at least a portion of the substrate. For example, the protective coating may be Cu selective such that the portion of the substrate covered by the protective coating corresponds to at least one or more copper features of the substrate, such as bond pads or other copper features. The protective coating applied to the substrate at step 1030 may include one or more inhibitor compounds, such as 5-mercapto-1-phenyl-tetrazole, 5-(4-methoxyphenyl)-2-amino1,3,4-thiadiazole, sulfathiazole, 5-amino1,3,4-thiadiazol 2-thiol, 1-phenyl-1H-tetrazole-5-thiol, 2-(2-dihydroxy-5-methyl)-phenyl-benzotriazole, 5-methyl-benzotriazole, amino tertiary butyl pyrazole, tetrazole, dodecane thiol, amino toluene, 1,2,4-triazole, cyproconazole, 4-(2-aminothiazol-4-yl)-phenol, 5-methyl-2-phenyl-2,4-dihydropyrazol-3-one, phenyl isothiocyanate; 4-methyl-5-imidazolecarbaldehyde, 5-(3-aminophenyl)-tetrazole, 2-amino-4-(4-chlorophenyl)-thiazole, 1-H-benzotriazole, 2-mercapto-benzoxazole, 5-methyl-benzotriazole, 5-methyl-benzimidazole, 2-mercapto benzimidazole, pyrazole, toly-triazole, 4-methyl-5-hydroxymethylimidazole, diniconazole, 4-(4-aminostyryl)-N,N-dimethylaniline, 8-methyl-benzotriazole, 3,5-diamino-1,2,4-triazole, phenyl urea, 5-(4-methoxyphenyl)-2-amino1,3,4-thiadiazole, 5-mercapto-1-phenyl-tetrazole, phenyl methyl benzotriazole, benzoxazole, other azole-based and non-azole-based compounds, or combinations thereof. As described above with reference to FIG. 2, the protective coating may be copper-selective such that the coating adheres to the one or more copper features of the substrate and any portions of the protective coating not adhered to the copper feature(s) may be removed. For example, in an aspect, the substrate may be rinsed a second time following application of the protective coating to remove excess coating material (e.g., the inhibitor compounds described above with reference to FIG. 2). As described above with reference to FIG. 2, the coating unit may be a bath coating unit (e.g., the bath coating unit 232 of FIG. 2) or a CVD coating unit (e.g., the CVD coating unit 234 of FIG. 2). In some aspects the substrate may be maintained in a wet state in between steps 1010, 1020, 1030, as described above with reference to FIG. 2.

In some embodiments, step 1030 of the method 1000 may include annealing the substrate subsequent to applying the protective coating. As described above, annealing may mitigate or remove minor imperfections in the protective coating after its application. In an aspect, the substrate is maintained in a storage facility for a period of time prior to the bonding. By using the protective coating one or more copper features of the substrate may be prevented from developing oxides or other negative artifacts that may reduce the quality of subsequent bonding processes, thereby improving the quality of any subsequently formed bonds. At step 1040, the method 1000 includes bonding copper pillars extending from the flip chip device to metallic features on the surface of the coated substrate.

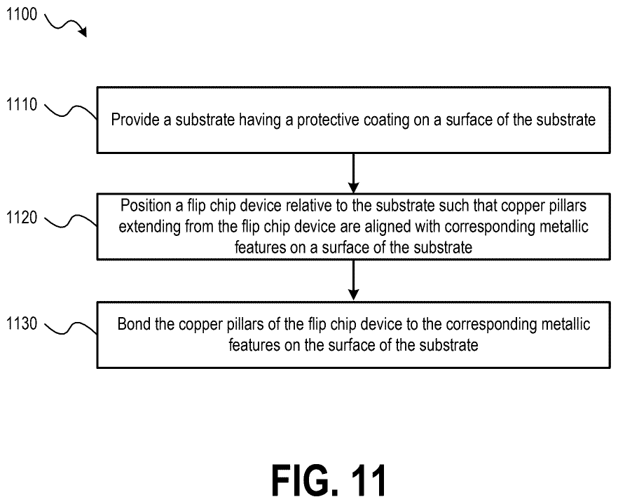

FIG. 11 is a flow diagram of another exemplary method 1100 for mounting Cu to solder bonding in accordance with aspects of the present disclosure. Like method 1000 of FIG. 10, the method 1100 may be performed using a system, such as the system 200 of FIG. 2, as described above. At step 1110, the method 1100 includes providing a substrate having copper features protected by a protective coating. As described above, the protective coating may be a Cu selective passivation coating applied to Cu features on the surface of the substrate to prevent oxidation during storage. For example, the method 1100 may be performed after the coated substrate has been maintained in the above-described storage facility for a period (e.g., days, weeks, months, years, or a combination thereof). At step 1120, the method 1100 includes positioning a flip chip device relative to the substrate such that copper pillars extending from the flip chip device are aligned with corresponding metallic features (e.g., Cu bond pads or other structures) on the surface of the substrate. At step 1130, the copper pillars of the flip chip device (e.g., having solder thereon) are bonded to the corresponding metallic features on the surface of the substrate.

As described above with reference to FIGS. 6-8, the bonding performed at step 1140 of method 1100 and step 1130 of method 1000 may be structurally improved as compared to other bonding processes, especially for Cu to solder bonds. For example, the bonds formed at each of steps 1040 and 1130 may exhibit improved strength (i.e., be less likely to break or for bonded wires to lift off their respective bonding pads or pillars). Such structural resiliency may improve the lifespan of devices and reduce failure rates, thereby enabling the benefits of Cu to solder bonds to be utilized in certain environments, such as automotive applications, where bonded devices may be subject to harsh environments or corrosive forces. In addition to improving device reliability and safety, using the method 1000 or the method 1100 and system 200 also removes common corrosion concerns due to inter-metallics and galvanic contact, e.g., as associated with common Cu—Al and Cu—Sn connections. As shown above, the bonding process described above with respect to method 1000, method 1100, and system 200 provide a chemistry-driven approach to selectively protect Cu features from oxidation via a wide selection of processes. Such capabilities enable low temperature vapor phase application of protective coatings for dry processes (e.g. for IC chip designs having features that can be damaged from liquid immersion). Additionally, unlike volatile corrosion inhibitors, the inhibitor compound(s) used to apply protective coatings in accordance with the concepts disclosed herein remain intact and bonded on Cu surfaces even in ambient conditions, making it ideal for situations where the substrates may require storage prior to performing bonding processes, such as may be encountered with substrates having Cu bond pad arrays, Cu traces, Cu pillars, Cu carriers, Cu trays, and the like. Additionally, as described above, the techniques disclosed herein may also enable selective control of coating thickness, such as by changing process conditions (e.g., exposure time, temperature, concentration of inhibitor compounds, etc.).

Although the present invention and its advantages have been described in detail, various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

Moreover, the scope of the present application is not intended to be limited to the particular embodiments of the process, machine, manufacture, composition of matter, means, methods and steps described in the specification.

What is claimed is:

1. A method of mounting a flip chip device onto a substrate, the method comprising:
cleaning a surface of a substrate prior to mounting a flip chip device onto the substrate;
rinsing the substrate to remove residual artifacts remaining on the surface subsequent to the cleaning;
subsequent to the rinsing, applying a protective coating to the surface of the substrate to produce a coated substrate; and
bonding copper pillars extending from the flip chip device to metallic features on the surface of the coated substrate.

2. The method of claim 1, wherein each of the copper pillars is capped with solder, and wherein the solder penetrates the protective coating covering the metallic features on the surface of the coated substrate to bond directly with the metallic features.

3. The method of claim 1, wherein the protective coating is applied by immersing the substrate in a solution comprising a solvent and one or more inhibitor compounds, and wherein the protective coating is formed from the one or more inhibitor compounds.

4. The method of claim 3, wherein the metallic features on the surface of the substrate are copper or Cu alloy structures, wherein the protective coating applied to the metallic features is copper-selective, and wherein the method further comprises:
rinsing the substrate subsequent to applying the protective coating to remove excess inhibitor compound from the surface of the substrate; and
annealing the substrate prior to the bonding.

5. The method of claim 1, wherein the protective coating is applied by placing the substrate in a chemical vapor deposition (CVD) chamber of a coating unit and heating one or more inhibitor compounds to vaporize the one or more inhibitor compounds, and wherein the protective coating is formed from deposition of the vaporized one or more inhibitor compounds on the surface of the substrate.

6. The method of claim 1, wherein the protective coating comprises one or more inhibitor compounds, and wherein the one or more inhibitor compounds comprise 5-mercapto-1-phenyl-tetrazole, 5-(4-methoxyphenyl)-2-amino1,3,4-thiadiazole, sulfathiazole, 5-amino1,3,4-thiadiazol 2-thiol, 1-phenyl-1H-tetrazole-5-thiol, 2-(2-dihydroxy-5-methyl)-phenyl-benzotriazole, 5-methyl-benzotriazole, amino tertiary butyl pyrazole, tetrazole, dodecane thiol, amino toluene, 1,2,4-triazole, cyproconazole, 4-(2-aminothiazol-4-yl)-phenol, 5-methyl-2-phenyl-2,4-dihydropyrazol-3-one, phenyl isothiocyanate; 4-methyl-5-imidazolecarbaldehyde, 5-(3-aminophenyl)-tetrazole, 2-amino-4-(4-chlorophenyl)-thiazole, 1-H-benzotriazole, 2-mercapto-benzoxazole, 5-methyl-benzotriazole, 5-methyl-benzimidazole, 2-mercapto benzimidazole, pyrazole, toly-triazole, 4-methyl-5-hydroxymethylimidazole, diniconazole, 4-(4-aminostyryl)-N,N-dimethylaniline, 8-methyl-benzotriazole, 3,5-diamino-1,2,4-triazole, phenyl urea, 5-(4-methoxyphenyl)-2-amino1,3,4-thiadiazole, 5-mercapto-1-phenyl-tetrazole, phenyl methyl benzotriazole, benzoxazole, other azole- and non-azole-based compounds, or combinations thereof.

7. The method of claim 1, wherein the substrate is maintained in a wet state in between the cleaning, the rinsing, and the applying of the protective coating.

8. The method of claim 1, wherein the substrate is maintained in a storage facility for a period of time prior to bonding.

9. The method of claim 1, wherein the copper pillars are bonded to the metallic features on the surface of the substrate after the protective coating is weakened by a plasma treatment.

10. The method of claim 9, wherein the plasma treatment involves etching the surface of the coated substrate with plasma to remove a portion of the protective coating covering the metallic features on the surface of the coated substrate.

11. A system comprising:
a cleaning unit configured to clean a surface of a substrate;
a rinsing unit configured to rinse the substrate to remove residual artifacts remaining on the surface subsequent to cleaning the surface by the cleaning unit;
a coating unit configured to apply a protective coating to the surface of the substrate to produce a coated substrate; and
a bonding unit configured to bond copper pillars on a flip chip device to metallic features on the surface of the coated substrate.

12. The system of claim 11, wherein the coating unit comprises a bath coating unit comprising a solution comprising a solvent and one or more inhibitor compounds, and wherein the protective coating is applied by immersing the metallic features in the solution.

13. The system of claim 12, wherein the protective coating is formed from the one or more inhibitor compounds, and wherein at least one of the one or more inhibitor compounds is copper selective.

14. The system of claim 11, further comprising an annealing unit configured to anneal the one or more metallic features subsequent to applying the protective coating and prior to the bonding.

15. The system of claim 11, wherein the cleaning unit comprises a wet etching unit, a dry etching unit, or both.

16. The system of claim 11, wherein the coating unit comprises a chemical vapor deposition (CVD) coating unit having a CVD chamber, wherein the protective coating is applied by placing the metallic features in the CVD chamber and heating one or more inhibitor compounds, wherein the one or more inhibitor compounds are vaporized by the heating, and wherein the protective coating is formed from deposition of the vaporized one or more inhibitor compounds on the metallic features on the surface of the substrate.

17. The system of claim 11, wherein the metallic features comprise bond pads or pillars made of Cu or Cu alloy.

18. The system of claim 11, wherein the protective coating is copper-selective, and wherein the metallic features comprise at least one of copper, copper alloys, plated copper, or combinations thereof.

19. The system of claim 11, wherein the coated substrate is maintained in a storage facility for a period prior to the bonding.

20. The system of claim 11, wherein each of the copper pillars is capped with solder, and wherein the solder penetrates the protective coating covering the metallic features on the surface of the coated substrate to bond directly with the metallic features.

21. The system of claim 11, wherein the copper pillars are bonded to the metallic features on the surface of the coated substrate after the protective coating is weakened by a plasma treatment.

22. The system of claim 21, wherein the plasma treatment involves etching the surface of the coated substrate with plasma to remove or modify a portion of the protective coating covering the metallic features on the surface of the coated substrate.
